(19) United States
(12) Patent Application Publication
(10) Pub. No.: US 2025/0185297 A1
(43) Pub. Date: Jun. 5, 2025

(54) METAL GATE RECESS STOP FOR GATE-ALL-AROUND FIELD EFFECT TRANSISTORS

(71) Applicant: QUALCOMM Incorporated, San Diego, CA (US)

(72) Inventors: Kwanyong LIM, San Diego, CA (US); Hyunwoo PARK, San Diego, CA (US); Junjing BAO, San Diego, CA (US); Chih-Sung YANG, Hsinchu City (TW); Ming-Huei LIN, New Taipei City (TW); Haining YANG, San Diego, CA (US)

(21) Appl. No.: 18/528,056

(22) Filed: Dec. 4, 2023

(51) Int. Cl. H01L 29/423; H01L 29/06; H01L 29/66; H01L 29/775; H01L 29/786

(52) U.S. Cl. CPC H10D 30/6735; H10D 30/014; H10D 30/43; H10D 30/6757; H10D 62/121

(57) ABSTRACT

A gate-all-around (GAA) field effect transistor (FET) structure and method for making the same is disclosed. In an aspects, a GAA FET includes a gate structure, extending in a first horizontal direction and disposed between first and second source/drain (S/D) epitaxial (EPI) structures and having a vertical metal gate structure with a first portion containing a set of vertically-stacked, horizontal channels connecting the first and second EPI S/D structures through the vertical metal gate structure, and a second portion having no channels. The GAA FET also includes a metal gate recess stop structure extending in the first horizontal direction and disposed above the first portion of the vertical metal gate structure, and a frontside inter-layer dielectric (ILD) layer disposed above the vertical metal gate structure and the first metal gate recess stop structure.

### BACKGROUND OF THE DISCLOSURE

### 1. Field of the Disclosure

This disclosure relates generally to semiconductor wafer process, and more specifically to gate-all-around (GAA) field effect transistors (FETs) structures and methods for making the same.

### 2. Description of the Related Art

Integrated circuit (IC) technology has achieved great strides in advancing computing power through miniaturization of electrical components. An IC device may be implemented in the form of an IC chip that has a set of circuits integrated thereon, including a plurality of active and passive components (e.g., transistors, diodes, capacitors, inductors, and/or resistors) and layers of contacts and interconnects above the active and passive components. In some aspects, the contacts and interconnects of an IC device are formed on the active and passive components on the front side of the IC device. As the sizes of the IC devices and the sizes of the components formed thereon become smaller, the available area for forming the contacts and interconnects also become smaller. As such, the routing complexity and/or the parasitic resistance and capacitance of the contacts and interconnects may increase and thus the manufacturing cost or the performance of the IC device may be negatively impacted.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a field effect transistor (FET) structure includes a gate structure, extending in a first horizontal direction and disposed between a first source/drain (S/D) epitaxial (EPI) structure and a second EPI S/D structure set apart in a second horizontal direction, the gate structure comprising a channel structure and a vertical metal gate structure, the channel structure comprising a plurality of vertically-stacked, horizontal channels connecting the first EPI S/D structure to the second EPI S/D structure in the second horizontal direction through the vertical metal gate structure that at least partially surrounds the plurality of vertically-stacked, horizontal channels, wherein the vertical metal gate structure contains a first portion in the first horizontal direction that contains the plurality of vertically-stacked, horizontal channels and a second portion in the first horizontal direction that does not contain the plurality of vertically-stacked, horizontal channels; a first metal gate recess stop structure extending in the first horizontal direction and disposed above the first portion of the vertical metal gate structure; and a frontside inter-layer dielectric (ILD) layer disposed above the vertical metal gate structure and the first metal gate recess stop structure.

In an aspect, a method for fabricating a FET structure includes providing a gate structure, extending in a first horizontal direction and disposed between a first EPI S/D structure and a second EPI S/D structure set apart in a second horizontal direction, the gate structure comprising a channel structure and a vertical metal gate structure, the channel structure comprising a plurality of vertically-stacked, horizontal channels connecting the first EPI S/D structure to the second EPI S/D structure in the second horizontal direction through the vertical metal gate structure that at least partially surrounds the plurality of vertically-stacked, horizontal channels, wherein the vertical metal gate structure contains a first portion in the first horizontal direction that contains the plurality of vertically-stacked, horizontal channels and a second portion in the first horizontal direction that does not contain the plurality of vertically-stacked, horizontal channels; providing a first metal gate recess stop structure extending in the first horizontal direction and disposed above the first portion of the vertical metal gate structure; and providing a frontside ILD layer disposed above the vertical metal gate structure and the first metal gate recess stop structure.

Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, wherein like reference numbers represent like parts, which are presented solely for illustration and not limitation of the disclosure.

FIGS. 1A, 1B, and 1C are a top view, a first cross-sectional view along a first horizontal axis, and a second cross-sectional view along a second horizontal axis, respectively, of a conventional semiconductor structure of an integrated circuit (IC) device comprising a gate-all-around (GAA) field effect transistor (FET).

FIGS. 2A, 2B, and 2C are a top view, a first cross-sectional view along a first horizontal axis, and a second cross-sectional view along a second horizontal axis, respectively, of a semiconductor structure of an IC device comprising a GAA FET with a metal gate recess stop, according to aspects of the disclosure.

FIG. 3 illustrates cross-sectional views of a semiconductor structure of an IC device during several stages of a conventional wafer process to fabricate a GAA FET.

FIG. 4 illustrates cross-sectional views of a semiconductor structure of an IC device during several stages of a wafer process to fabricate a GAA FET with a metal gate recess stop, according to aspects of the disclosure.

FIG. 5 illustrates cross-sectional views of a semiconductor structure of an IC device during several stages of a wafer process to fabricate a GAA FET with a metal gate recess stop, according to other aspects of the disclosure.

FIG. 6 illustrates cross-sectional views of a semiconductor structure of an IC device during several stages of a wafer process to fabricate a GAA FET with a metal gate recess stop, according to yet other aspects of the disclosure.

FIG. 7 is a flowchart of an example process associated with metal gate recess stop for GAA FETs, according to aspects of the disclosure.

FIG. 8 illustrates a mobile device in accordance with some examples of the disclosure.

FIG. 9 illustrates various electronic devices that may be integrated with any of the aforementioned integrated device or semiconductor device in accordance with various examples of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

A gate-all-around (GAA) field effect transistor (FET) structure and method for making the same is disclosed. In an aspects, a GAA FET includes a gate structure, extending in a first horizontal direction and disposed between first and second source/drain (S/D) epitaxial (EPI) structures and having a vertical metal gate structure with a first portion containing a set of vertically-stacked, horizontal channels connecting the first and second EPI S/D structures through the vertical metal gate structure, and a second portion having no channels. The FET also includes a metal gate recess stop structure extending in the first horizontal direction and disposed above the first portion of the vertical metal gate structure, and a frontside inter-layer dielectric (ILD) layer disposed above the vertical metal gate structure and the first metal gate recess stop structure.

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

Particular aspects of the subject matter described in this disclosure can be implemented to realize one or more of the following potential advantages. Because the recessed EPI S/D structures extend below the gate structures, backside contacts are far enough away from the gate structures that there is less chance that a process error (e.g., an etch process that etched too deep, a lithography process that was not completely aligned to the wafer, etc.) will cause the backside contact to short circuit with the gate. Also, since the contact does not have to fit solely within the space between adjacent gates, a backside contact can be made with a larger surface area, which reduces contact resistance.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage, or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

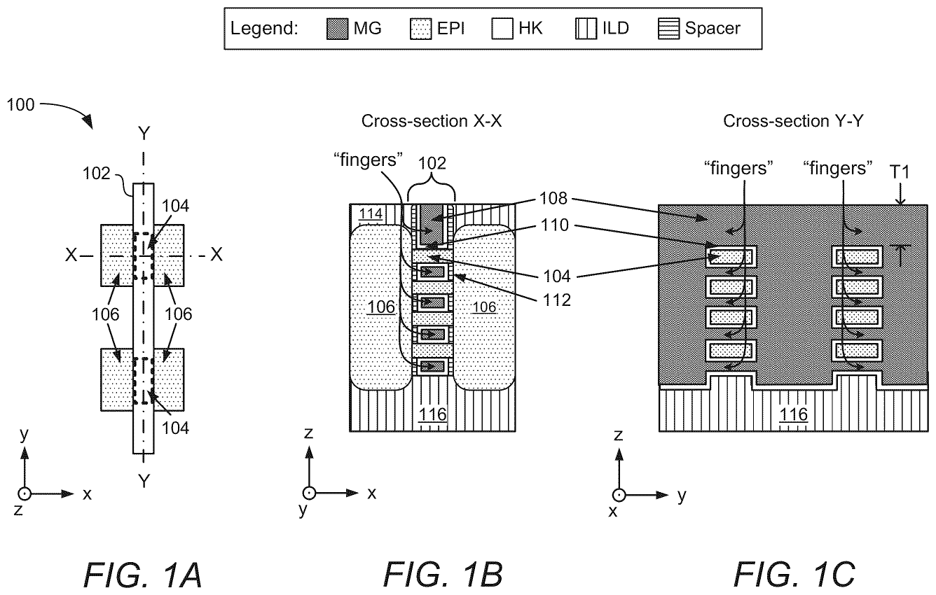

FIGS. 1A, 1B, and 1C are a top view, a first cross-sectional view along a first horizontal axis, and a second cross-sectional view along a second horizontal axis, respectively, of a conventional semiconductor structure 100 of an integrated circuit (IC) device comprising a gate-all-around (GAA) field effect transistor (FET). As shown in FIG. 1A, the semiconductor structure 100 includes a gate stack 102 having a width in a first direction (e.g., the x direction) and having a length along a second direction (e.g., the y direction). As used herein, the term “gate stack” refers to a structure that includes a metal gate and which may also include dielectric material, an inner spacer, and other structural components, including one or more nano-sheet channels 104 that extend in the x direction to electrically connect epitaxial (EPI) source/drain (S/D) regions 106. As used herein, the terms “gate” and “gate stack” are synonymous unless specifically indicated as otherwise.

FIG. 1B is a cross-sectional view of the semiconductor structure 100 along cut-line X-X. As can be seen in FIG. 1B, each gate cross-section includes a metal gate 108 through which the channels 104 extend, insulated from the metal gate 108 by a dielectric 110 and insulated from the EPI S/D regions 106 by an inner spacer 112. As shown in FIG. 1B, a top inter-layer dielectric (ILD) layer 114 covers the top of the gate stack 102 and EPI S/D regions 106, and a bottom ILD layer 116 covers the bottoms of the gate stack 102 and the EPI S/D regions 106. The portions of the metal gate 108 above and below the channels 104 are colloquially referred to as “fingers.”

FIG. 1C is a cross-sectional view of the semiconductor structure 100 along cut-line Y-Y. In the example shown in FIG. 1B and FIG. 1C, the top finger of the metal gate 108, i.e., the finger that is above the top-most channel 104, has a vertical dimension T1 that is larger than the vertical dimension of the other fingers of the metal gate 108. For a GAA FET, T1 may be referred to as “the thickness of the top metal finger” of the metal gate 108. A conventional GAA FET fabrication process imposes a minimum value for T1, to take into account non-uniformities that may occur during the portion of the wafer process that etches or planarizes the metal gate 108 over the top-most channel 104. That is, if T1 is too small, the top-most channel 104 may be inadvertently exposed during the etch or planarization step. Thus, a common wafer process requirement is that T1 be >=10 nm to account for wafer process variability. This top portion of the metal gate 108 contributes to unwanted gate capacitance. It is therefore desired to fabricate a GAA FET to have the portion of the metal gate 108 over the top-most channel 104 have a height that is less than T1 without the danger of accidentally etching into and exposing the top-most channel 104.

Accordingly, one approach to solve this problem is to add an additional sacrificial SiGe layer and a metal gate recess stop material on top of the Si/SiGe nanosheet stack. The metal gate recess stop material protects the top finger of the metal gate during the gate recess process, which may include an etch step and/or a chemical/mechanical planarization (CMP) step. This protection allows the thickness of the top finger of the gate to be precisely controlled, which allows the top finger of the gate to be much thinner than the minimum value of T1 defined for a conventional process, and thus allows the height of the entire metal gate structure to be reduced. For example, the top finger of the gate can have a thickness of only 4-8 nm. An advantage of this approach is that the use of the metal gate recess stop material results in excellent metal gate height uniformity, locally and globally, for both short gate lengths and long gate lengths. Another advantage of this approach is that gate-to-contact overlap capacitance can be reduced as a result of the reduced height of the entire metal gate structure.

Examples of metal gate recess stop material include, but are not limited to, dielectrics, such as aluminum oxide (Al₂O₃), aluminum nitride (AlN), titanium dioxide (TiO₂), silicon carbide (SiC), silicon nitride (SiN), and tantalum (III) oxide (Ta₂O₃), or conductors, such as ruthenium (Ru), molybdenum (Mo), cobalt (Co), aluminum (Al), titanium (Ti), tantalum (Ta), and polysilicon (poly-Si). Yet another advantage of this technique for GAA FETs in particular is that even if the etch step etches the metal gate so much that the top finger of the metal gate does not connect from one side of the channel stack to the other, the other fingers of the metal gate are still intact and thus the GAA remains operational.

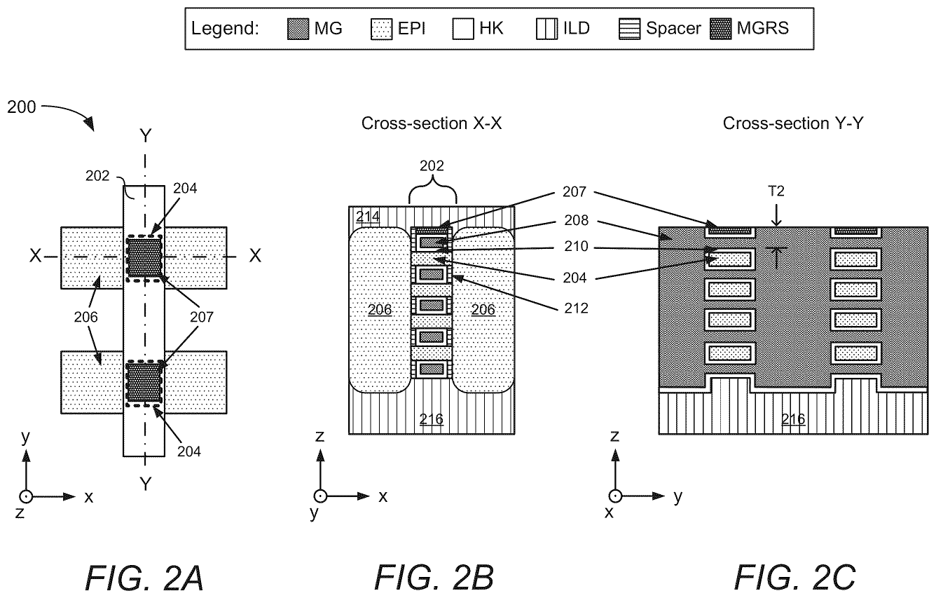

FIGS. 2A, 2B, and 2C are a top view, a first cross-sectional view along a first horizontal axis, and a second cross-sectional view along a second horizontal axis, respectively, of a semiconductor structure of an IC device comprising a GAA FET with a metal gate recess stop, according to aspects of the disclosure. As shown in FIG. 2A, the semiconductor structure 200 includes a gate stack 202 having a width in a first direction (e.g., the x direction) and having a length along a second direction (e.g., the y direction). As used herein, the term “gate stack” refers to a structure that includes a metal gate and which may also include dielectric material, an inner spacer, and other structural components, including one or more nano-sheet channels 204 that extend in the x direction to electrically connect EPI S/D regions 206. As used herein, the terms “gate” and “gate stack” are synonymous unless specifically indicated as otherwise. FIG. 2A shows the locations of metal gate recess stop material 207 on the top surface of the gate stack 202 located above the channels 204.

FIG. 2B is a cross-sectional view of the semiconductor structure 200 along cut-line X-X. As can be seen in FIG. 2B, each gate cross-section includes a metal gate 208 through which the channels 204 extend, insulated from the metal gate 208 by a dielectric 210 and insulated from the EPI S/D regions 206 by an inner spacer 212. As shown in FIG. 2B, a top inter-layer dielectric (ILD) layer 214 covers the tops of the gate stack 202 and EPI S/D regions 206, and a bottom ILD layer 216 covers the bottoms of the gate stack 202 and the EPI S/D regions 206. As shown in FIG. 2B, the semiconductor structure 200 also includes a recess stop material 207 above metal gate 208 above the top-most channel 204. This recess stop material 207 provides a physical barrier to prevent an etch or planarization process from inadvertently exposing the top-most channel 204 during the etch or planarization step. In some aspects, the recess stop material 207 comprises a dielectric. In some aspects, the recess stop material 207 is harder than the metal gate 208 or is otherwise more resistant to being removed during the etch or planarization process compared to the metal gate 208.

FIG. 2C is a cross-sectional view of the semiconductor structure 200 along cut-line Y-Y. As can be seen in FIG. 2C, the metal gate 208 extends a distance T2 above the top-most channel 204, where T2 is less than T1. T2 may be referred to as “the thickness of the top metal finger” of the metal gate 208. As a result, the top finger of metal gate 208 in FIG. 2 contributes less gate capacitance compared to the top finger of the metal gate 108 in FIG. 1. As a result, gate-to-contact overlap capacitance can be reduced by 20-60% because gate height above the top-most channel can be reduced from ˜10 nm to 4-8 nm level.

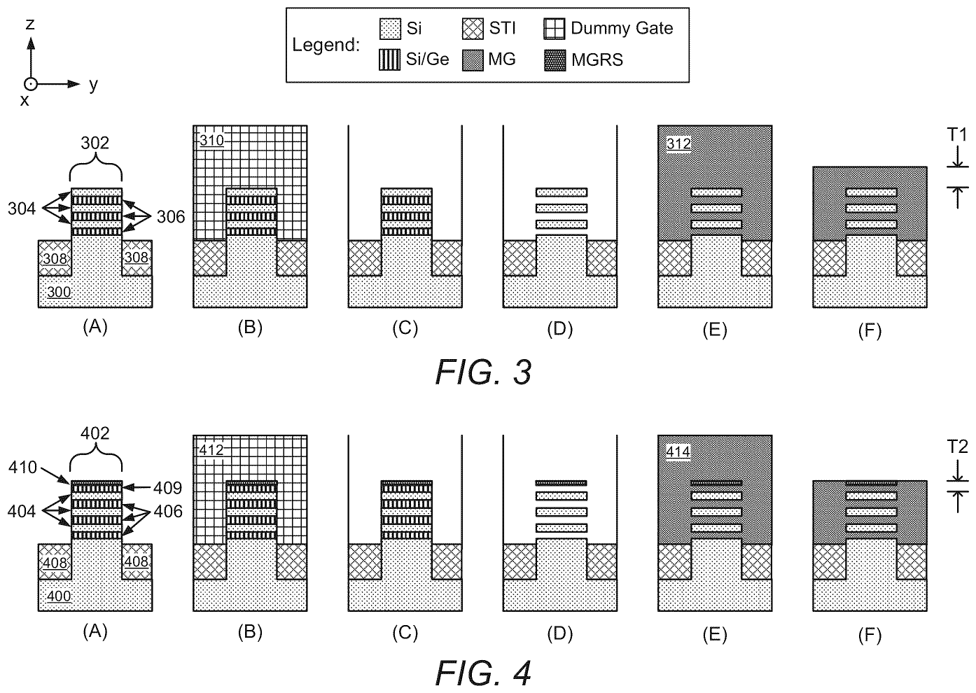

FIG. 3 illustrates cross-sectional views of a semiconductor structure of an IC device during several stages of a conventional wafer process to fabricate a GAA FET. Cross-sectional view (A) shows a substrate 300 upon which has been fabricated a gate stack 302 having alternating layers of Si channels 304 and sacrificial SiGe layers 306 and being separated from adjacent gate stacks by shallow trench isolation (STI) structures 308. Cross-sectional view (B) shows the result after deposition of a dummy gate 310 and a S/D process. Cross-sectional view (C) shows the result after removal of the dummy gate 310. Cross-sectional view (D) shows the result after removal of the sacrificial SiGe layers 306. Cross-sectional view (E) shows the result after deposition of a high-K dielectric (not shown for simplicity) and a metal gate 312. Cross-sectional view (F) shows the result after a metal gate recess process, which may include etching and/or chemical/mechanical planarization (CMP) steps, resulting in a top metal gate finger of thickness T1.

FIG. 4 illustrates cross-sectional views of a semiconductor structure of an IC device during several stages of a wafer process to fabricate a GAA FET with a metal gate recess stop, according to aspects of the disclosure. In FIG. 4, cross-sectional view (A) shows a substrate 400 upon which has been fabricated a gate stack 402 having alternating layers of Si channels 404 and sacrificial SiGe layers 406 and being separated from adjacent gate stacks by shallow trench isolation (STI) structures 408. Compared to the gate stack 302 in FIG. 2, however, the gate stack 402 in FIG. 4 has an additional sacrificial SiGe layer 409 that is topped with a metal gate recess stop material 410. Cross-sectional view (B) shows the result after deposition of a dummy gate 412 and a S/D process. Cross-sectional view (C) shows the result after removal of the dummy gate 412. Cross-sectional view (D) shows the result after removal of the sacrificial SiGe layers 406 and sacrificial layer 409. Cross-sectional view (E) shows the result after deposition of a high-K dielectric (not shown for simplicity) and a metal gate 414. Cross-sectional view (F) shows the result after a metal gate recess process, which may include etching and/or CMP steps, resulting in a top metal gate finger of thickness T2. The metal gate recess stop material 410 is intended to be sacrificial, i.e., some, none, or all of it may be removed during the etching and/or CMP steps without affecting the operation of the FET. Since the FET is a GAA FET, even if the metal gate 414 is etched on either side of the metal gate recess stop material 410 such that the metal gate above the top-most Si channel 404 no longer electrically connects the gate metal on either side of the Si channels 404, there will still be other paths below the top-most Si channel 404.

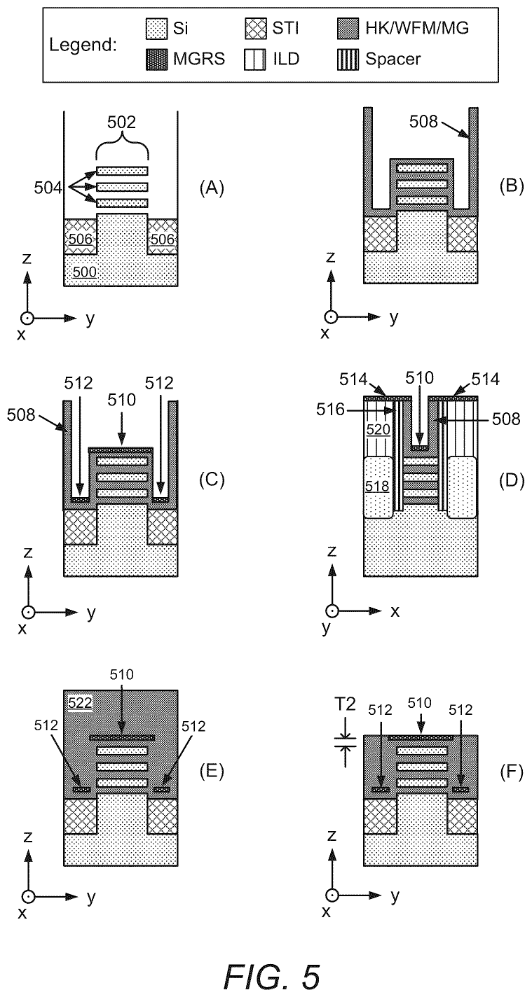

FIG. 5 illustrates cross-sectional views of a semiconductor structure of an IC device during several stages of a wafer process to fabricate a GAA FET with a metal gate recess stop, according to other aspects of the disclosure. In FIG. 5, cross-sectional view (A) shows a substrate 500 upon which has been fabricated a gate stack 502 having alternating layers of horizontal Si channels 504 (with the sacrificial SiGe layers already removed) and being separated from adjacent gate stacks by shallow trench isolation (STI) structures 506. Cross-sectional view (B) shows the result after deposition high-K dielectric (not shown for simplicity) and a work function metal layer 508. Cross-sectional views (C) and (D) show the result after deposition of metal gate recess stop material to form a first metal gate recess stop structure 510, as viewed along the y axis and the x axis, respectively. In some aspects, the metal gate recess stop material may be deposited by a vertical deposition, such as physical vapor deposition (PVD), to avoid sidewall dielectric deposition.

The semiconductor structure shown in FIG. 5 differs from the semiconductor structure shown in FIG. 4 in that the deposition of the metal gate recess stop material creates a second metal gate recess stop structure 512 disposed within what will become the second portion of the vertical metal gate structure. The second metal gate recess stop structure 512 is lower in the z direction than the first metal gate recess stop structure 510, as can be seen in cross-sectional view (C). The deposition of the metal gate recess stop material also creates a third metal gate recess stop structure 514 disposed on either side of the first metal gate recess stop structure 510 in the x direction but higher in the z direction than the first metal gate recess stop structure 510, as can be seen in cross-sectional view (D). In some aspects, the second metal gate recess stop structure 512 is lower in the z direction than a bottom-most channel of the plurality of vertically-stacked, horizontal Si channels 504. Cross-sectional view (D) also shows the inner spacers 516, EPI S/D regions 518, and frontside ILD 520. Cross-sectional view (E) shows the result after deposition additional gate metal to create a completed metal gate 522. Cross-sectional view (F) shows the result after a metal gate recess process, which may include etching and/or CMP steps, resulting in a top metal gate finger of thickness T2. One benefit of the semiconductor structure shown in FIG. 5 is that it can be made without adding an additional sacrificial SiGe layer (such as the sacrificial SiGe layer 409 in FIG. 4); the height of the nanosheet stack therefore remains the same, which can mitigate any potential yield risks that might have resulted from having a taller nanosheet stack and subsequent gate etch.

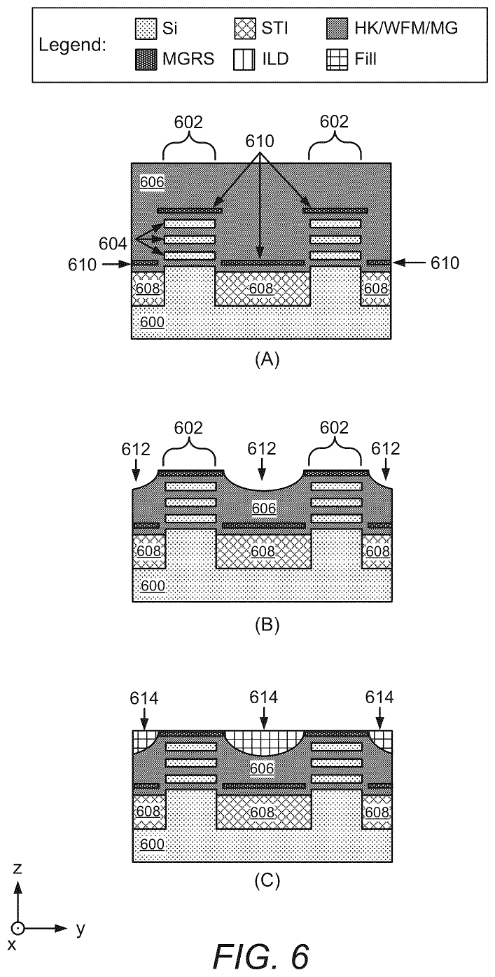

FIG. 6 illustrates cross-sectional views of a semiconductor structure of an IC device during several stages of a wafer process to fabricate a GAA FET with a metal gate recess stop, according to yet other aspects of the disclosure. In FIG. 6, cross-sectional view (A) shows a substrate 600 upon which has been fabricated gate stacks 602 having alternating layers of Si channels 604 surrounded by a vertical metal gate structure 606 and being separated from adjacent gate stacks by shallow trench isolation (STI) structures 608. Metal gate recess stop material 610 is present above the top-most Si channel 604 and between the gate stacks 602. Cross-sectional view (B) shows the result after a selective metal gate recess process. This process leaves divots or concavities 612 on the top surface of the vertical metal gate structure 606. Cross-sectional view (C) shows the result after the concavities are filled with a fill material 614 and a planarization step is performed. In some aspects, the fill material 614 may comprise a dielectric material. This can reduce gate-to-contact overlap capacitance further, without any additional mask. Examples of fill material 614 include, but are not limited to, Al₂O₃, AlN, titanium dioxide (TiO₂), silicon carbide (SiC), SiN, and tantalum (III) oxide (Ta₂O₃). Thus, in some aspects, such as when the fill material 614 is the same as the material used for an ILD layer deposited on top of the structure shown in cross-sectional view (C), for example, a portion of the ILD layer extends vertically into the second portion of the vertical metal gate structure 606 to a depth lower in the vertical direction than a bottom surface of the first metal gate recess stop structure 602. In some aspects, such as the example shown in cross-sectional view (C), the portion of the ILD layer that extends vertically into the second portion of the vertical metal gate structure 606 extends to a depth lower in the vertical direction than a top surface of a top-most channel of the plurality of vertically-stacked, horizontal channels 604.

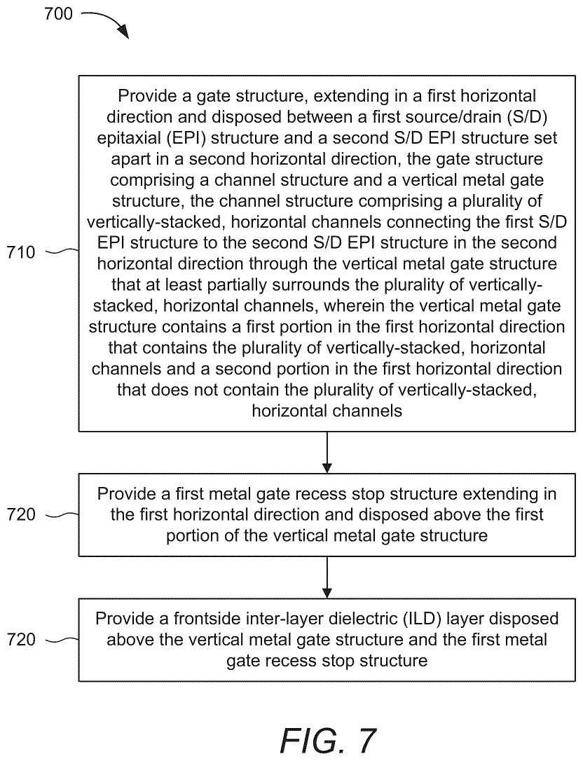

FIG. 7 is a flowchart of an example process 700 associated with metal gate recess stop for GAA FETs according to aspects of the disclosure.

As shown in FIG. 7, process 700 may include, at block 710, providing a gate structure, extending in a first horizontal direction and disposed between a first source/drain (S/D) epitaxial (EPI) structure and a second EPI S/D structure set apart in a second horizontal direction, the gate structure comprising a channel structure and a vertical metal gate structure, the channel structure comprising a plurality of vertically-stacked, horizontal channels connecting the first EPI S/D structure to the second EPI S/D structure in the second horizontal direction through the vertical metal gate structure that at least partially surrounds the plurality of vertically-stacked, horizontal channels, wherein the vertical metal gate structure contains a first portion in the first horizontal direction that contains the plurality of vertically-stacked, horizontal channels and a second portion in the first horizontal direction that does not contain the plurality of vertically-stacked, horizontal channels.

As further shown in FIG. 7, process 700 may include, at block 720, providing a first metal gate recess stop structure extending in the first horizontal direction and disposed above the first portion of the vertical metal gate structure.

As further shown in FIG. 7, process 700 may include, at block 730, providing a frontside inter-layer dielectric (ILD) layer disposed above the vertical metal gate structure and the first metal gate recess stop structure.

In some aspects, the first metal gate recess stop structure disposed above the first portion of the vertical metal gate structure extends in the first horizontal direction over at least a dimension of a top-most channel of the plurality of vertically-stacked, horizontal channels in the first horizontal direction.

In some aspects, the first metal gate recess stop structure comprises at least one of aluminum oxide (Al₂O₃), aluminum nitride (AlN), titanium dioxide (TiO₂), silicon carbide (SiC), silicon nitride (SiN), tantalum (III) oxide (Ta2O3), ruthenium (Ru), molybdenum (Mo), cobalt (Co), aluminum (Al), titanium (Ti), tantalum (Ta), or polysilicon.

In some aspects, a portion of the vertical metal gate structure that is above a top-most channel of the plurality of vertically-stacked, horizontal channels and below the first metal gate recess stop structure has a vertical dimension of 4 nm to 8 nm.

In some aspects, process 700 includes providing a second metal gate recess stop structure disposed within the second portion of the vertical metal gate structure lower in a vertical direction than the first metal gate recess stop structure.

In some aspects, the second metal gate recess stop structure is lower in the vertical direction than a bottom-most channel of the plurality of vertically-stacked, horizontal channels.

In some aspects, a portion of the ILD layer extends vertically into the second portion of the vertical metal gate structure to a depth lower in the vertical direction than a bottom surface of the first metal gate recess stop structure.

In some aspects, the portion of the ILD layer that extends vertically into the second portion of the vertical metal gate structure extends to a depth lower in the vertical direction than a top surface of a top-most channel of the plurality of vertically-stacked, horizontal channels.

In some aspects, the portion of the ILD layer that extends vertically into the second portion of the vertical metal gate structure comprises silicon dioxide (SiO2).

In some aspects, the first metal gate stop structure consists of a different material than the vertical metal gate structure.

Process 700 may include additional implementations, such as any single implementation or any combination of implementations described below and/or in connection with one or more other processes described elsewhere herein. Although FIG. 7 shows example blocks of process 700, in some implementations, process 700 may include additional blocks, fewer blocks, different blocks, or differently arranged blocks than those depicted in FIG. 7. Additionally, or alternatively, two or more of the blocks of process 700 may be performed in parallel.

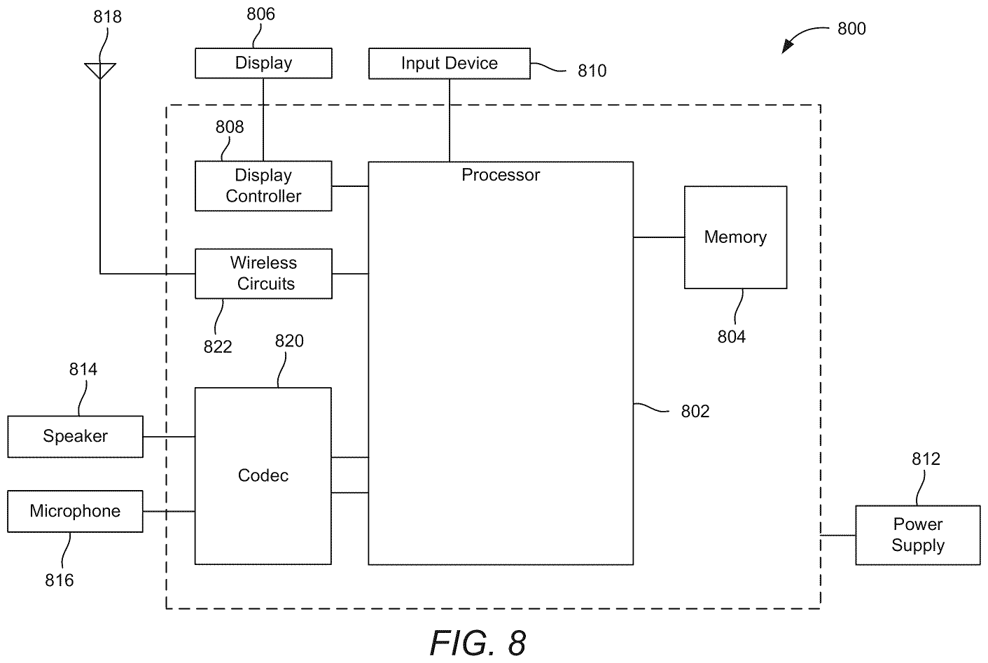

FIG. 8 illustrates a mobile device 800, according to aspects of the disclosure. In some aspects, the mobile device 800 may be implemented by including one or more IC devices manufactured based on the examples described in this disclosure.

In some aspects, mobile device 800 may be configured as a wireless communication device. As shown, mobile device 800 includes processor 802. Processor 802 may be communicatively coupled to memory 804 over a link, which may be a die-to-die or chip-to-chip link. Mobile device 800 also includes display 806 and display controller 808, with display controller 808 coupled to processor 802 and to display 806. The mobile device 800 may include input device 810 (e.g., physical, or virtual keyboard), power supply 812 (e.g., battery), speaker 814, microphone 816, and wireless antenna 818. In some aspects, the power supply 812 may directly or indirectly provide the supply voltage for operating some or all of the components of the mobile device 800.

In some aspects, FIG. 8 may include coder/decoder (CODEC) 820 (e.g., an audio and/or voice CODEC) coupled to processor 802; speaker 814 and microphone 816 coupled to CODEC 820; and wireless circuits 822 (which may include a modem, RF circuitry, filters, etc.) coupled to wireless antenna 818 and to processor 802.

In some aspects, one or more of processor 802, display controller 808, memory 804, CODEC 820, and wireless circuits 822 may include one or more IC devices including semiconductor structures manufactured according to the examples described in this disclosure.

It should be noted that although FIG. 8 depicts a mobile device 800, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

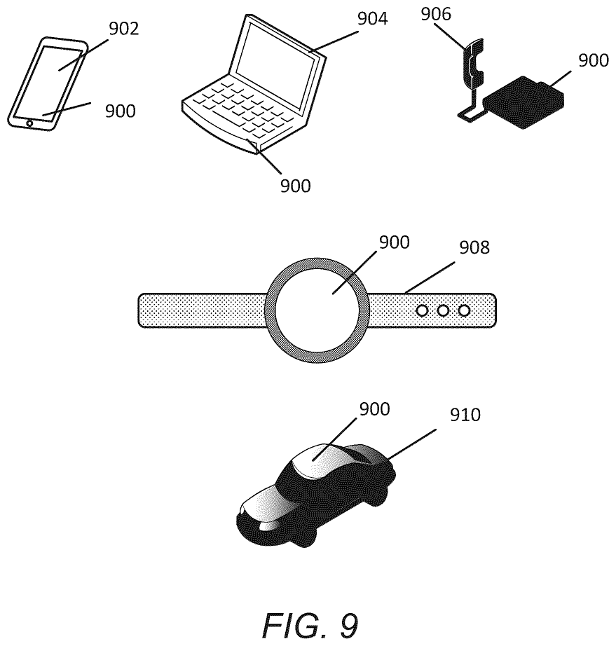

FIG. 9 illustrates various electronic devices that may be integrated with any of the aforementioned devices, semiconductor devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 902, a laptop computer device 904, a fixed location terminal device 906, a wearable device 908, or automotive vehicle 910 may include a semiconductor device 900 (e.g., semiconductor structure 200) as described herein. The devices 902, 904, 906 and 908 and the vehicle 910 illustrated in FIG. 9 are merely exemplary. Other apparatuses or devices may also feature the semiconductor device 900 including, but not limited to, a group of devices that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A field effect transistor (FET) structure, comprising: a gate structure, extending in a first horizontal direction and disposed between a first source/drain (S/D) epitaxial (EPI) structure and a second EPI S/D structure set apart in a second horizontal direction, the gate structure comprising a channel structure and a vertical metal gate structure, the channel structure comprising a plurality of vertically-stacked, horizontal channels connecting the first EPI S/D structure to the second EPI S/D structure in the second horizontal direction through the vertical metal gate structure that at least partially surrounds the plurality of vertically-stacked, horizontal channels, wherein the vertical metal gate structure contains a first portion in the first horizontal direction that contains the plurality of vertically-stacked, horizontal channels and a second portion in the first horizontal direction that does not contain the plurality of vertically-stacked, horizontal channels; a first metal gate recess stop structure extending in the first horizontal direction and disposed above the first portion of the vertical metal gate structure; and a frontside inter-layer dielectric (ILD) layer disposed above the vertical metal gate structure and the first metal gate recess stop structure.

Clause 2. The FET structure of clause 1, wherein the first metal gate recess stop structure disposed above the first portion of the vertical metal gate structure extends in the first horizontal direction over at least a dimension of a top-most channel of the plurality of vertically-stacked, horizontal channels in the first horizontal direction.

Clause 3. The FET structure of any of clauses 1 to 2, wherein the first metal gate recess stop structure comprises at least one of aluminum oxide (Al2O3), aluminum nitride (AlN), titanium dioxide (TiO2), silicon carbide (SiC), silicon nitride (SiN), tantalum (III) oxide (Ta2O3), ruthenium (Ru), molybdenum (Mo), cobalt (Co), aluminum (Al), titanium (Ti), tantalum (Ta), or polysilicon.

Clause 4. The FET structure of any of clauses 1 to 3, wherein a portion of the vertical metal gate structure that is above a top-most channel of the plurality of vertically-stacked, horizontal channels and below the first metal gate recess stop structure has a vertical dimension of 4 nm to 8 nm.

Clause 5. The FET structure of any of clauses 1 to 4, further comprising a second metal gate recess stop structure disposed within the second portion of the vertical metal gate structure lower in a vertical direction than the first metal gate recess stop structure.

Clause 6. The FET structure of clause 5, wherein the second metal gate recess stop structure is lower in the vertical direction than a bottom-most channel of the plurality of vertically-stacked, horizontal channels.

Clause 7. The FET structure of any of clauses 1 to 6, wherein a portion of the ILD layer extends vertically into the second portion of the vertical metal gate structure to a depth lower in the vertical direction than a bottom surface of the first metal gate recess stop structure.

Clause 8. The FET structure of clause 7, wherein the portion of the ILD layer that extends vertically into the second portion of the vertical metal gate structure extends to a depth lower in the vertical direction than a top surface of a top-most channel of the plurality of vertically-stacked, horizontal channels.

Clause 9. The FET structure of any of clauses 1 to 8, wherein the portion of the ILD layer that extends vertically into the second portion of the vertical metal gate structure comprises silicon dioxide (SiO2).

Clause 10. The FET structure of any of clauses 1 to 9, wherein the first metal gate stop structure consists of a different material than the vertical metal gate structure.

Clause 11. A method for fabricating a field effect transistor (FET) structure, the method comprising: providing a gate structure, extending in a first horizontal direction and disposed between a first source/drain (S/D) epitaxial (EPI) structure and a second EPI S/D structure set apart in a second horizontal direction, the gate structure comprising a channel structure and a vertical metal gate structure, the channel structure comprising a plurality of vertically-stacked, horizontal channels connecting the first EPI S/D structure to the second EPI S/D structure in the second horizontal direction through the vertical metal gate structure that at least partially surrounds the plurality of vertically-stacked, horizontal channels, wherein the vertical metal gate structure contains a first portion in the first horizontal direction that contains the plurality of vertically-stacked, horizontal channels and a second portion in the first horizontal direction that does not contain the plurality of vertically-stacked, horizontal channels; providing a first metal gate recess stop structure extending in the first horizontal direction and disposed above the first portion of the vertical metal gate structure; and providing a frontside inter-layer dielectric (ILD) layer disposed above the vertical metal gate structure and the first metal gate recess stop structure.

Clause 12. The method of clause 11, wherein the first metal gate recess stop structure disposed above the first portion of the vertical metal gate structure extends in the first horizontal direction over at least a dimension of a top-most channel of the plurality of vertically-stacked, horizontal channels in the first horizontal direction.

Clause 13. The method of any of clauses 11 to 12, wherein the first metal gate recess stop structure comprises at least one of aluminum oxide (Al2O3), aluminum nitride (AlN), titanium dioxide (TiO2), silicon carbide (SiC), silicon nitride (SiN), tantalum (III) oxide (Ta2O3), ruthenium (Ru), molybdenum (Mo), cobalt (Co), aluminum (Al), titanium (Ti), tantalum (Ta), or polysilicon.

Clause 14. The method of any of clauses 11 to 13, wherein a portion of the vertical metal gate structure that is above a top-most channel of the plurality of vertically-stacked, horizontal channels and below the first metal gate recess stop structure has a vertical dimension of 4 nm to 8 nm.

Clause 15. The method of any of clauses 11 to 14, further comprising providing a second metal gate recess stop structure disposed within the second portion of the vertical metal gate structure lower in a vertical direction than the first metal gate recess stop structure.

Clause 16. The method of clause 15, wherein the second metal gate recess stop structure is lower in the vertical direction than a bottom-most channel of the plurality of vertically-stacked, horizontal channels.

Clause 17. The method of any of clauses 11 to 16, wherein a portion of the ILD layer extends vertically into the second portion of the vertical metal gate structure to a depth lower in the vertical direction than a bottom surface of the first metal gate recess stop structure.

Clause 18. The method of clause 17, wherein the portion of the ILD layer that extends vertically into the second portion of the vertical metal gate structure extends to a depth lower in the vertical direction than a top surface of a top-most channel of the plurality of vertically-stacked, horizontal channels.

Clause 19. The method of any of clauses 11 to 18, wherein the portion of the ILD layer that extends vertically into the second portion of the vertical metal gate structure comprises silicon dioxide (SiO2).

Clause 20. The method of any of clauses 11 to 19, wherein the first metal gate stop structure consists of a different material than the vertical metal gate structure.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. A field effect transistor (FET) structure, comprising:
a gate structure, extending in a first horizontal direction and disposed between a first epitaxial (EPI) source/drain (S/D) structure and a second EPI S/D structure set apart in a second horizontal direction, the gate structure comprising a channel structure and a vertical metal gate structure, the channel structure comprising a plurality of vertically-stacked, horizontal channels connecting the first EPI S/D structure to the second EPI S/D structure in the second horizontal direction through the vertical metal gate structure that at least partially surrounds the plurality of vertically-stacked, horizontal channels, wherein the vertical metal gate structure contains a first portion in the first horizontal direction that contains the plurality of vertically-stacked, horizontal channels and a second portion in the first horizontal direction that does not contain the plurality of vertically-stacked, horizontal channels;
a first metal gate recess stop structure extending in the first horizontal direction and disposed above the first portion of the vertical metal gate structure; and
a frontside inter-layer dielectric (ILD) layer disposed above the vertical metal gate structure and the first metal gate recess stop structure.

2. The FET structure of claim 1, wherein the first metal gate recess stop structure disposed above the first portion of the vertical metal gate structure extends in the first horizontal direction over at least a dimension of a top-most channel of the plurality of vertically-stacked, horizontal channels in the first horizontal direction.

3. The FET structure of claim 1, wherein the first metal gate recess stop structure comprises at least one of aluminum oxide (Al₂O₃), aluminum nitride (AlN), titanium dioxide (TiO₂), silicon carbide (SiC), silicon nitride (SiN), tantalum (III) oxide (Ta₂O₃), ruthenium (Ru), molybdenum (Mo), cobalt (Co), aluminum (Al), titanium (Ti), tantalum (Ta), or polysilicon.

4. The FET structure of claim 1, wherein a portion of the vertical metal gate structure that is above a top-most channel of the plurality of vertically-stacked, horizontal channels and below the first metal gate recess stop structure has a vertical dimension of 4 nm to 8 nm.

5. The FET structure of claim 1, further comprising a second metal gate recess stop structure disposed within the second portion of the vertical metal gate structure lower in a vertical direction than the first metal gate recess stop structure.

6. The FET structure of claim 5, wherein the second metal gate recess stop structure is lower in the vertical direction than a bottom-most channel of the plurality of vertically-stacked, horizontal channels.

7. The FET structure of claim 1, wherein a portion of the ILD layer extends vertically into the second portion of the vertical metal gate structure to a depth lower in the vertical direction than a bottom surface of the first metal gate recess stop structure.

8. The FET structure of claim 7, wherein the portion of the ILD layer that extends vertically into the second portion of the vertical metal gate structure extends to a depth lower in the vertical direction than a top surface of a top-most channel of the plurality of vertically-stacked, horizontal channels.

9. The FET structure of claim 1, wherein the portion of the ILD layer that extends vertically into the second portion of the vertical metal gate structure comprises silicon dioxide (SiO₂).

10. The FET structure of claim 1, wherein the first metal gate stop structure consists of a different material than the vertical metal gate structure.

11. A method for fabricating a field effect transistor (FET) structure, the method comprising:
providing a gate structure, extending in a first horizontal direction and disposed between a first source/drain (S/D) epitaxial (EPI) structure and a second EPI S/D structure set apart in a second horizontal direction, the gate structure comprising a channel structure and a vertical metal gate structure, the channel structure comprising a plurality of vertically-stacked, horizontal channels connecting the first EPI S/D structure to the second EPI S/D structure in the second horizontal direction through the vertical metal gate structure that at least partially surrounds the plurality of vertically-stacked, horizontal channels, wherein the vertical metal gate structure contains a first portion in the first horizontal direction that contains the plurality of vertically-stacked, horizontal channels and a second portion in the first horizontal direction that does not contain the plurality of vertically-stacked, horizontal channels;
providing a first metal gate recess stop structure extending in the first horizontal direction and disposed above the first portion of the vertical metal gate structure; and
providing a frontside inter-layer dielectric (ILD) layer disposed above the vertical metal gate structure and the first metal gate recess stop structure.

12. The method of claim 11, wherein the first metal gate recess stop structure disposed above the first portion of the vertical metal gate structure extends in the first horizontal direction over at least a dimension of a top-most channel of the plurality of vertically-stacked, horizontal channels in the first horizontal direction.

13. The method of claim 11, wherein the first metal gate recess stop structure comprises at least one of aluminum oxide (Al₂O₃), aluminum nitride (AlN), titanium dioxide (TiO₂), silicon carbide (SiC), silicon nitride (SiN), tantalum (III) oxide (Ta₂O₃), ruthenium (Ru), molybdenum (Mo), cobalt (Co), aluminum (Al), titanium (Ti), tantalum (Ta), or polysilicon.

14. The method of claim 11, wherein a portion of the vertical metal gate structure that is above a top-most channel of the plurality of vertically-stacked, horizontal channels and below the first metal gate recess stop structure has a vertical dimension of 4 nm to 8 nm.

15. The method of claim 11, further comprising providing a second metal gate recess stop structure disposed within the second portion of the vertical metal gate structure lower in a vertical direction than the first metal gate recess stop structure.

16. The method of claim 15, wherein the second metal gate recess stop structure is lower in the vertical direction than a bottom-most channel of the plurality of vertically-stacked, horizontal channels.

17. The method of claim 11, wherein a portion of the ILD layer extends vertically into the second portion of the vertical metal gate structure to a depth lower in the vertical direction than a bottom surface of the first metal gate recess stop structure.

18. The method of claim 17, wherein the portion of the ILD layer that extends vertically into the second portion of the vertical metal gate structure extends to a depth lower in the vertical direction than a top surface of a top-most channel of the plurality of vertically-stacked, horizontal channels.

19. The method of claim 11, wherein the portion of the ILD layer that extends vertically into the second portion of the vertical metal gate structure comprises silicon dioxide (SiO₂).

20. The method of claim 11, wherein the first metal gate stop structure consists of a different material than the vertical metal gate structure.
